(19) United States
(12) Patent Application Publication
(10) Pub. No.: US 2026/0032933 A1
(43) Pub. Date: Jan. 29, 2026

(54) COMPACT INDUCTORS

(71) Applicant: Analog Devices, Inc., Wilmington, MA (US)

(72) Inventor: Vikas Paduvalli, San Jose, CA (US)

(21) Appl. No.: 18/781,224

(22) Filed: Jul. 23, 2024

(51) Int. Cl. H01L 23/00; H01L 23/367; H01L 25/16

(52) U.S. Cl. CPC H10D 1/20; H01L 23/367; H01L 24/13; H01L 24/16; H01L 25/16; H01L 2224/13147; H01L 2224/13647; H01L 2224/16245; H01L 2924/1206

(57) ABSTRACT

Compact inductors are disclosed herein. In certain embodiments, a compact inductor includes a ferrite core including a ferrite body, and a first conductive pillar and a second conductive pillar that each extend from a bottom surface of the ferrite body to a top surface of the ferrite body. Additionally, the compact inductor includes a planar substrate coupled to the top surface of the ferrite body. The planar substrate includes interconnect that electrically connects the first conductive pillar to the second conductive pillar.

### FIELD OF THE DISCLOSURE

Embodiments of the invention relate to electronic systems, and more particularly, to inductors.

### BACKGROUND

High performance inductors can be desired for a variety of applications. In one example, an inductor is used in a switching regulator. For example, the switching regulator can employ one or more switches (for instance, power transistors) coupled in series and/or parallel with an output terminal that provides an output voltage to a load through an inductor. Additionally, a controller turns the switches ON and OFF to control delivery of current pulses to the output terminal through the inductor, which converts the switched pulses into a steady load current.

### SUMMARY OF THE DISCLOSURE

Compact inductors are disclosed herein. In certain embodiments, a compact inductor includes a ferrite core including a ferrite body, and a first conductive pillar and a second conductive pillar that each extend from a bottom surface of the ferrite body to a top surface of the ferrite body. Additionally, the compact inductor includes a planar substrate coupled to the top surface of the ferrite body. The planar substrate includes interconnect that electrically connects the first conductive pillar to the second conductive pillar. Thus, the planar substrate is used in part to form a coil of the compact inductor. Furthermore, use of the planar substrate to interface to the ferrite core enables lower cost, superior thermal performance and/or lower DC resistance (DCR) relative to a U-shaped copper conductor.

In one aspect, a compact inductor includes a ferrite core including a ferrite body, a first conductive pillar extending through the ferrite body from a first surface of the ferrite body to a second surface of the ferrite body opposite the first surface, and a second conductive pillar extending through the ferrite body from the first surface to the second surface. The compact inductor further includes a planar substrate coupled to the first surface of the ferrite body, the planar substrate electrically connecting a first end of the first conductive pillar to a first end of the second conductive pillar. A second end of the first conductive pillar provides a first inductor terminal, and a second end of the second conductive pillar provides a second inductor terminal.

In another aspect, a power conversion module includes a circuit board, and an inductor attached to the circuit board. The inductor includes a ferrite core including a ferrite body, a first conductive pillar extending through the ferrite body from a first surface of the ferrite body to a second surface of the ferrite body opposite the first surface, and a second conductive pillar extending through the ferrite body from the first surface to the second surface. The inductor further includes a planar substrate coupled to the first surface of the ferrite body, the planar substrate electrically connecting a first end of the first conductive pillar to a first end of the second conductive pillar. A second end of the first conductive pillar provides a first inductor terminal that is electrically connected to the circuit board, and a second end of the second conductive pillar provides a second inductor terminal that is electrically connected to the circuit board.

In another aspect, a method of forming an inductor includes attaching a ferrite core to a planar substrate, the ferrite core including a ferrite body, a first conductive pillar extending through the ferrite body from a first surface of the ferrite body to a second surface of the ferrite body opposite the first surface, and a second conductive pillar extending through the ferrite body from the first surface to the second surface. The method further includes electrically connecting a first end of the first conductive pillar to a first end of the second conductive pillar using the planar substrate, providing a first inductor terminal using a second end of the first conductive pillar and providing a second inductor terminal using a second end of the second conductive pillar.

### BRIEF DESCRIPTION OF THE DRAWINGS

FIG. 1A is a perspective view of a compact inductor according to one embodiment.

FIG. 1B is an expanded perspective view of the compact inductor of FIG. 1A.

FIG. 2A is a thermal graph of a compact inductor according to one embodiment.

FIG. 2B is a thermal graph of one example of a bent copper inductor.

FIG. 3A is a perspective view of another embodiment of a compact inductor prior to attachment of direct bonded copper (DBC).

FIG. 3B is a side view of the compact inductor of FIG. 3A after attachment of the DBC.

FIG. 4A is a side view of a compact inductor according to another embodiment.

FIG. 4B is a side view of a compact inductor according to another embodiment.

FIG. 4C is a side view of a compact inductor according to another embodiment.

FIG. 5A is a side view of a power conversion module according to one embodiment.

FIG. 5B is a side view of a power conversion module according to another embodiment.

FIG. 5C is a side view of a power conversion module according to another embodiment.

FIG. 6 is a side view of a switching regulator system according to another embodiment.

### DETAILED DESCRIPTION OF EMBODIMENTS

The following detailed description of embodiments presents various descriptions of specific embodiments of the invention. However, the invention can be embodied in a multitude of different ways. In this description, reference is made to the drawings where like reference numerals may indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Certain inductors have a U-shaped copper conductor that is surrounded in part by a ferrite core. Since ferrite is not an effective thermal conductor, such inductors suffer from the U-shaped copper conductor running much hotter compared to the ferrite core. Although it is desirable to thicken the U-shaped copper conductor to better dissipate heat and to reduce parasitics, thickening the U-shaped copper conductor may not be feasible since bending thick copper into a U-shape can be extremely difficult.

Compact inductors are disclosed herein. In certain embodiments, a compact inductor includes a ferrite core including a ferrite body, and a first conductive pillar and a second conductive pillar that each extend from a bottom surface of the ferrite body to a top surface of the ferrite body. Additionally, the compact inductor includes a planar substrate coupled to the top surface of the ferrite body. The planar substrate includes a first interconnect that electrically connects the first conductive pillar to the second conductive pillar.

Thus, the planar substrate is used in part to form a coil of the compact inductor. Furthermore, use of the planar substrate to interface to the ferrite core enables lower cost, superior thermal performance and/or lower DC resistance (DCR) relative to a U-shaped copper conductor. Not only does the superior thermal performance reduce heating, but also reduces DCR since conductors such as copper have lower resistivity at lower temperatures.

In certain implementations the planar substrate can interconnect the terminals of multiple pairs of inductor pillars to provide a multiphase inductor with two or more phases.

The planar substrate can be implemented in a variety of ways.

In a first example, the planar substrate includes direct bonded copper (DBC). For example, a ceramic substrate can include copper that is directly bonded to the ceramic. Although copper and ceramic are dissimilar electronic materials, direct copper bonding processing can be achieved, for example, by forming a copper-oxygen eutectic at high temperature and then cooling the system to create an interfacial layer that bonds the copper metal to a ceramic, such as alumina.

In another example, the planar substrate includes a printed circuit board (PCB) having patterned conductive traces that electrically connect the pillars of the ferrite core to one another as desired. Such a PCB can include traces that are soldered, welded, and/or otherwise electrically connected to the pillars.

The inductors herein can achieve high inductance values while maintaining low DCR as the height profile is scaled. Such inductors are well suited for high density modules that includes one or more inductors for power conversion. Thus, the inductor can be compactly integrated into a power converter to provide a small footprint inductor that leaves board area for other components, such as input capacitors, output capacitors, and/or semiconductor components.

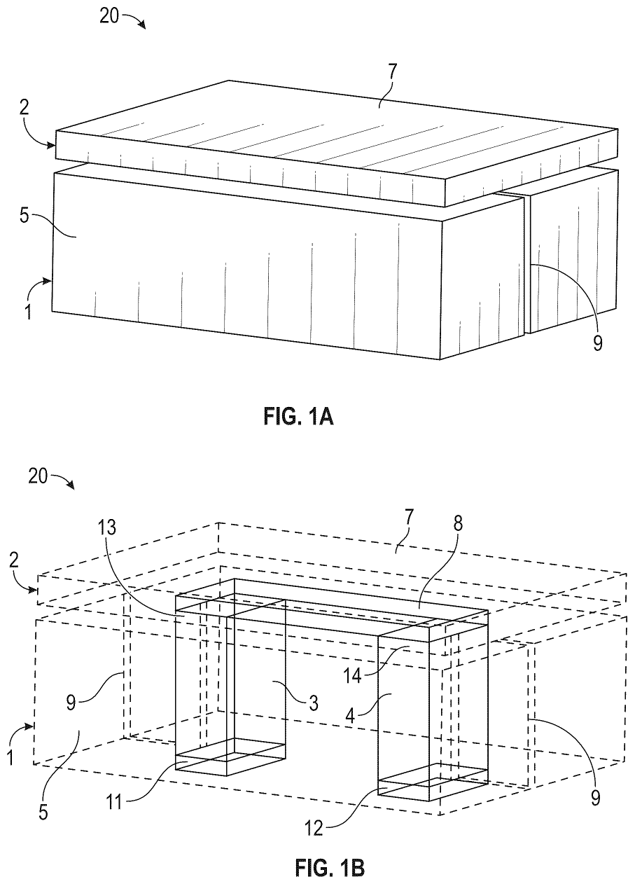

FIG. 1A is a perspective view of a compact inductor 20 according to one embodiment. The compact inductor 20 includes a ferrite core 1 and a DBC 2. FIG. 1B is an expanded perspective view of the compact inductor 20 of FIG. 1A in which the ferrite core 1 and the DBC 2 are depicted transparently using dashing.

The ferrite core 1 includes a ferrite body 5 through which a first conductive pillar 3 and a second conductive pillar 4 have been formed. The first conductive pillar 3 and the second conductive pillar 4 extend from a first or top surface of the ferrite body 5 to a second or bottom surface of the ferrite body 5. Additionally, a first end of the first conductive pillar 3 is exposed on the top surface of the ferrite body 5 to provide a first coil terminal 13, while a first end of the second conductive pillar 14 is exposed on the top surface of the ferrite body 5 to provide a second coil terminal 14. The DBC 2 serves to electrically connect the first coil terminal 13 to the second coil terminal 14. Thus, the DBC 2 forms in part a coil of the compact inductor 20.

With continuing reference to FIGS. 1A and 1B, a second end of the first conductive pillar 3 is exposed on the bottom surface of the ferrite body 5 to provide a first inductor port or terminal 11, while a second end of the second conductive pillar 4 is exposed on the bottom surface of the ferrite body 5 to provide a second inductor port or terminal 12. The first inductor terminal 11 and the second inductor terminal 12 serve as terminals of an inductor that can be electrically connected to a switcher or other electronic circuit as desired.

In certain implementations, the conductive pillars 3-4 are formed of copper. Advantageously, the conductive pillars 3-4 are substantially straight (for example, nominally straight absent manufacturing variation) and thus do not include bends. Thus, the copper pillars can be formed to be thick and need not be bent. Although the copper pillars 3-4 are shown as having a rectangular cross-section, the copper pillars 3-4 can have other cross-sectional shapes, such as square, circular, elliptical, hexagonal, or other desired shape.

In certain implementations, the copper pillars 3-4 each have a thickness of at least 0.5 mm. Although example thickness dimensions have been described above, other implementations are possible such as copper pillar thicknesses that are thinner for lower power applications.

By using thick copper pillars, improved thermal performance is achieved. For example, since ferrite is not an effective thermal conductor, the copper pillars can run much hotter compared to the ferrite core 5. By using thick copper pillars, more heat can be effectively dissipated from the inductor, thus allowing the inductor to be used in high current applications such as power regulation.

Moreover, the DBC 2 can be directly bonded (for example, directly soldered) to the copper pillars without needing to use a thermal interface material (for instance, a thermal compound) that adds resistance. This results in cooler performance.

In the illustrated embodiment, notches 9 have been formed along the sides of the ferrite body 5. The notches 9 extend vertically in parallel with the conductive pillars 3-4, in this example. In some implementations, the notches 9 provide a gap in the ferrite body 5, such as an air gap. The notches 9 aid in controlling an inductance value of the compact inductor 20 and/or in improving the inductor's saturation characteristics.

In the illustrated embodiment, the DBC 2 includes a ceramic substrate 7 and a copper conductor or shim 8 that is directly bonded to the ceramic substrate 7. The copper conductor 8 connects the first coil terminal 13 of the first conductive pillar 3 to the second coil terminal 14 of the second conductive pillar 4.

The ceramic substrate 7 can be formed of a variety of materials including, for example, aluminum nitride, silicon nitride, and/or aluminum oxide (alumina). In certain implementations, the ceramic thickness is selected to be in the range of 0.25 mm to 1 mm and/or the copper thickness is selected to be in the range of 0.3 mm to 0.8 mm.

Although example thickness dimensions have been described above, other implementations are possible.

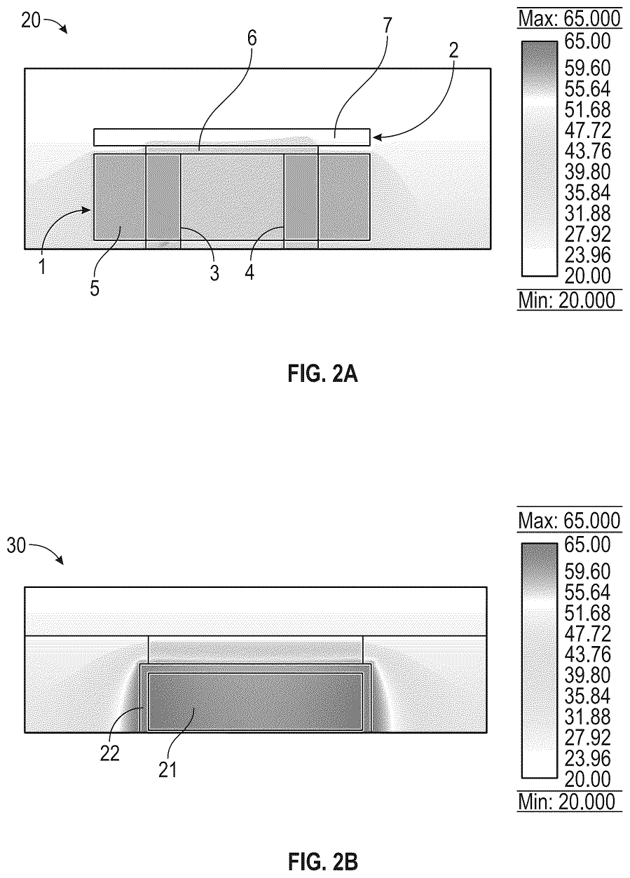

FIG. 2A is a thermal graph of for one implementation of the compact inductor 20 of FIGS. 1A and 1B. FIG. 2B is a thermal graph of one example of a bent copper inductor 30 that includes a ferrite body 21 and a bent copper staple 22.

As shown by a comparison of FIGS. 2A and 2B, the implementation of the compact inductor 20 exhibits superior heat performance relative to the bent copper inductor 30.

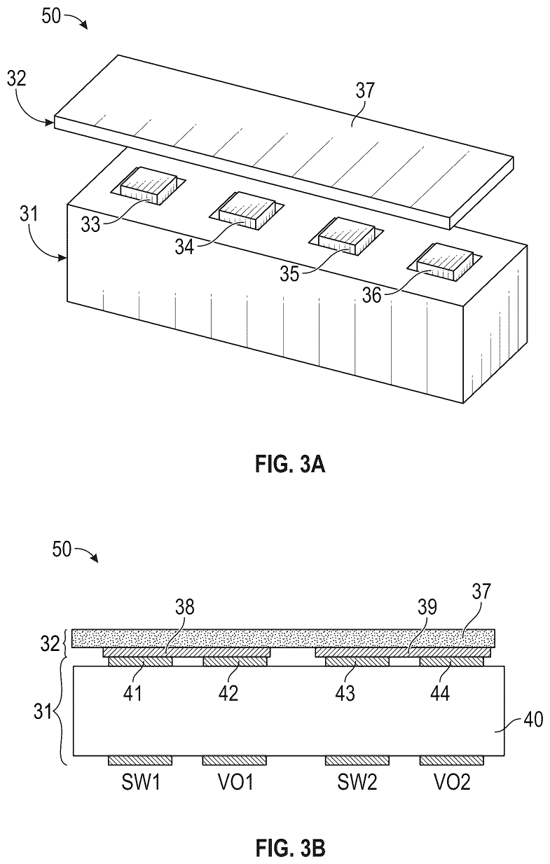

FIG. 3A is a perspective view of another embodiment of a compact inductor 50 prior to attachment of DBC 32. FIG. 3B is a side view of the compact inductor 50 of FIG. 3A after attachment of the DBC 32.

As shown in FIGS. 3A and 3B, the compact inductor 50 includes a ferrite core 31 and the DBC 32. The ferrite core 31 includes a ferrite body 40 through which a first copper pillar 33, a second copper pillar 34, a third copper pillar 35, and a fourth copper pillar 36 formed therethrough.

In the illustrated embodiment, the DBC 32 includes a ceramic substrate 37, a first copper shim 38 bonded to the ceramic substrate 37, and a second copper shim 39 bonded to the copper substrate 37.

The first copper shim 38 electrically connects a top end 41 of the first copper pillar 33 to a top end 42 of the second copper pillar 34. Furthermore, a bottom end of the first copper pillar 33 serves as a first inductor terminal SW1 for connecting to a first switcher output or other desired circuit, and a bottom end of the second copper pillar 34 serves as a second inductor terminal VOI for providing a first output voltage in a switcher application.

With continuing reference to FIGS. 3A and 3B, the second copper shim 38 electrically connects a top end 43 of the third copper pillar 35 to a top end 44 of the fourth copper pillar 36. Furthermore, a bottom end of the third copper pillar 35 serves as a third inductor terminal SW2 for connecting to a second switcher output or other desired circuit, and a bottom end of the fourth copper pillar 36 serves as a fourth inductor terminal VO2 for providing a second output voltage in a switcher application.

The compact inductor 50 serves as a multiphase inductor that can be used in a multichannel switcher application. For example, the inductor terminals SW1 and VO1 can correspond to a first phase of the multiphase inductor and be connected to a first channel of a dual channel switcher, while the inductor terminals SW2 and VO2 can correspond to a second phase of the multiphase inductor and be connected to a second channel of the dual channel switcher.

Accordingly, the first inductor terminal SW1, the first copper pillar 33, the first copper shim 38, the second copper pillar 34, and the second inductor terminal VOI operate as a first inductive structure. Additionally, the third inductor terminal SW2, the third copper pillar 36, the second copper shim 39, the fourth copper pillar 36, and the fourth inductor terminal VO2 operate as a second inductive structure. The first inductive structure and the second inductive structure can be electromagnetically coupled or uncoupled to one another based on implementation.

Although FIGS. 3A and 3B illustrate a multiphase inductor with two inductive structures, more or fewer inductive structures can be included.

In certain implementations, encapsulation or overmold is included as desired for the compact inductor 50 to aid in protecting the compact inductor 50 from damage. In one example, overmold is included over the DBC 32, with the overmold etched to expose the copper shims 38-39 to allow electrical connection to the copper pillars 33-36.

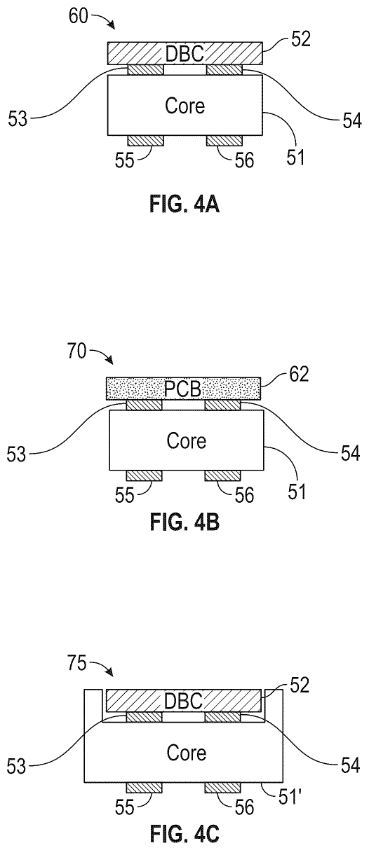

FIG. 4A is a side view of a compact inductor 60 according to another embodiment. The compact inductor 60 includes a ferrite core 51 and a DBC 52.

In the illustrated embodiment, a first copper pillar and a second copper pillar are provided through the ferrite core 51. Additionally, the DBC 52 connects a top end 53 of the first copper pillar to a top end 54 of the second copper pillar. Furthermore, a bottom end 55 of the first copper pillar serves as a first inductor terminal, while a bottom end 56 of the second copper pillar serves as a second inductor terminal.

FIG. 4B is a side view of a compact inductor 70 according to another embodiment. The compact inductor 70 includes a ferrite core 51 and a PCB 62.

The compact inductor 70 of FIG. 4B is similar to the compact inductor 60 of FIG. 4A, except that the compact inductor 60 of FIG. 4A uses traces of a PCB 62 to electrically connect the top end 53 of the first copper pillar to the top end 54 of the second copper pillar.

Any of the embodiments herein can use a PCB to provide connections between conductive pillars of a ferrite core.

FIG. 4C is a side view of a compact inductor 75 according to another embodiment. The compact inductor 75 includes a ferrite core 51′ and a DBC 52. The compact inductor 75 of FIG. 4C is similar to the compact inductor 60 of FIG. 4A, except that the ferrite core 51′ of the compact inductor 75 of FIG. 4C includes a recess in which the DBC 52 is positioned. Thus, a portion of the ferrite core 51′ laterally surrounds the DBC 52. Such a configuration can provide further enhancements in thermal performance.

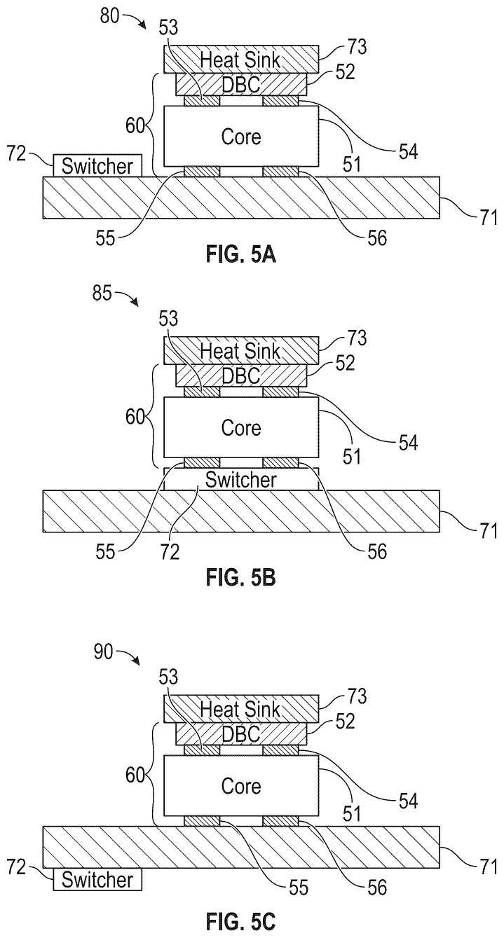

FIG. 5A is a side view of a power conversion module 80 according to one embodiment. The power conversion module 80 includes a circuit board 71 to which a switcher integrated circuit (IC) or die 72 is attached. The compact inductor 60 of FIG. 4A is also attached to the circuit board 71 adjacent to the switcher die 72. The circuit board 71 provides electrical connections that connect the first inductor terminal 55 and the second inductor terminal 56 of the compact inductor 60 to the switcher die 72 and/or other components on the circuit board 71 as desired.

In the illustrated embodiment, a heat sink 73 is included on a side of the DBC 52 opposite the ferrite core 52. The heat sink 73 aids in removing heat from the compact inductor 60 arising from operation of the switcher die 72. For example, the heat can arise from a flow of current from the switcher die 72 through the inductor 60 while providing power conversion.

In certain implementations, a ceramic substrate of the DBC 52 is less than 1 mm thick to aid in transferring heat out of the compact inductor 60.

The DBC 52 can aid in transferring heat out of the compact inductor 60 while also acting as an electrical isolator between the heat sink 73 and the inductor's conductors. For example, in certain implementations the heat sink 73 is grounded and the DBC 52 provides electrical isolation between the grounded heat sink and copper conductors of the inductor 60.

FIG. 5B is a side view of a power conversion module 85 according to another embodiment. The power conversion module 85 of FIG. 5B is similar to the power conversion module 80 of FIG. 5A, except that in the embodiment of FIG. 5B the compact inductor 60 is stacked over the switcher die 72, which is attached to the circuit board 71. Thus, the switcher die 72 is positioned between the compact inductor 60 and the circuit board 71, in this embodiment.

FIG. 5C is a side view of a power conversion module 90 according to another embodiment. The power conversion module 90 of FIG. 5C is similar to the power conversion module 80 of FIG. 5A, except that in the embodiment of FIG. 5C the compact inductor 60 and the switcher die 72 are attached to opposite sides of the circuit board 71.

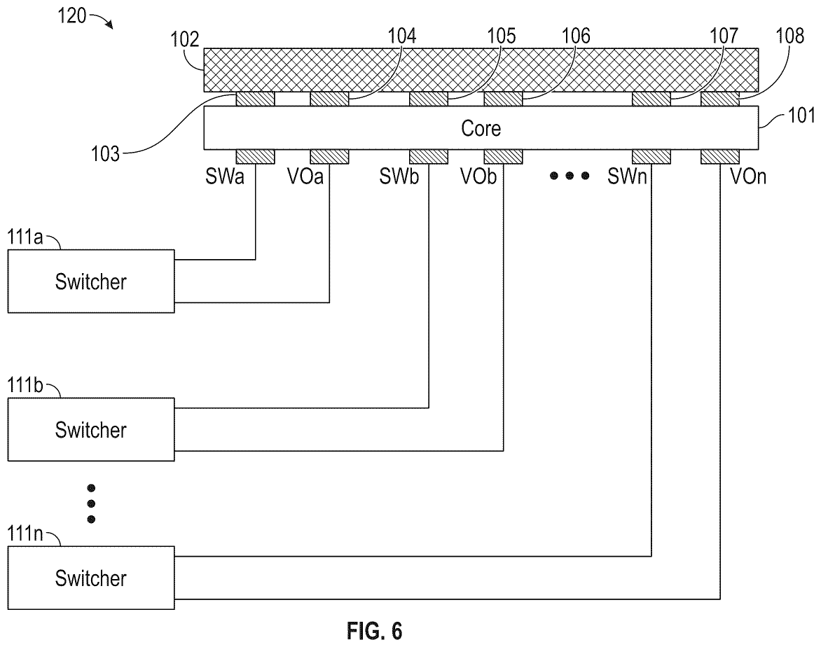

Any of the compact inductors herein can be used in a power conversion module, such as the power conversion modules of FIG. 5A-5C. [0053] FIG. 6 is a side view of a switching regulator system 120 according to another embodiment. The switching regulator system 120 includes a compact inductor 120 including a ferrite core 101 and a DBC 102. The ferrite core 101 is illustrated as including six copper pillars through a ferrite body, although more or fewer copper pillars can be included as indicated by the ellipses. The switching regulator system 120 further includes switchers 111a, 111b, . . . 111n for connecting to the compact inductor 120.

With continuing reference to FIG. 6, The DBC 102 electrically connects a top end 103 of a first copper pillar to a top end 104 of the second copper pillar. Additionally, the DBC 102 electrically connects a top end 105 of a third copper pillar to a top end 106 of the fourth copper pillar. Furthermore, the DBC 102 electrically connects a top end 107 of a fifth copper pillar to a top end 108 of the sixth copper pillar.

The bottom ends of the first and second copper pillars provide inductor terminals SWa/VOa for connecting the switcher 111a. Additionally, the bottom ends of the third and fourth copper pillars provide inductor terminals SWb/VOb for connecting the switcher 111b, while the bottom ends of the fifth and sixth copper pillars provide inductor terminals SWn/VOn for connecting the switcher 111n.

Any number of switchers and inductor phases can be provided as needed for a particular application.

### Applications

Devices employing the above-described schemes can be implemented into various electronic devices in a wide range of applications including, but not limited to, bus converters, high current distributed power systems, telecom systems, datacom systems, storage systems, and automotive systems. Thus, examples of electronic devices that can be implemented with the inductors herein include, but are not limited to, communication systems, consumer electronic products, electronic test equipment, communication infrastructure, servers, automobiles, etc.

### Conclusion

The foregoing description may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments. Accordingly, the scope of the present invention is defined only by reference to the appended claims.

Although the claims presented here are in single dependency format for filing at the USPTO, it is to be understood that any claim may depend on any preceding claim of the same type except when that is clearly not technically feasible.

What is claimed is:

1. A compact inductor comprising:
a ferrite core including a ferrite body, a first conductive pillar extending through the ferrite body from a first surface of the ferrite body to a second surface of the ferrite body opposite the first surface, and a second conductive pillar extending through the ferrite body from the first surface to the second surface; and
a planar substrate coupled to the first surface of the ferrite body, the planar substrate electrically connecting a first end of the first conductive pillar to a first end of the second conductive pillar,
wherein a second end of the first conductive pillar provides a first inductor terminal, and a second end of the second conductive pillar provides a second inductor terminal.

2. The compact inductor of claim 1, wherein the planar substrate comprises direct bonded copper (DBC).

3. The compact inductor of claim 2, wherein the DBC comprises a ceramic substrate and a copper conductor bonded to the ceramic substrate, the copper conductor electrically connecting the first end of the first conductive pillar to the first end of the second conductive pillar.

4. The compact inductor of claim 3, wherein the ceramic substrate comprises at least one of aluminum nitride, silicon nitride, or aluminum oxide.

5. The compact inductor of claim 3, wherein the first conductive pillar and the second conductive pillar are formed of copper.

6. The compact inductor of claim 2, further comprising a heat sink coupled to the DBC opposite the ferrite core.

7. The compact inductor of claim 1, wherein the planar substrate comprises a printed circuit board (PCB) having a conductive trace electrically connecting the first end of the first conductive pillar to the first end of the second conductive pillar.

8. The compact inductor of claim 1, wherein the ferrite core further includes a third conductive pillar extending through the ferrite body from the first surface to the second surface and a fourth conductive pillar extending through the ferrite body from the first surface to the second surface, the planar substrate electrically connecting a first end of the third conductive pillar to a first end of the fourth conductive pillar.

9. The compact inductor of claim 8, wherein a second end of the third conductive pillar provides a third inductor terminal, and a second end of the second conductive pillar provides a fourth inductor terminal, the first inductor terminal and the second inductor terminal providing a first inductor phase, and the third inductor terminal and the fourth inductor terminal providing a second inductor phase.

10. A power conversion module comprising:
a circuit board; and
an inductor attached to the circuit board, the inductor comprising:
a ferrite core including a ferrite body, a first conductive pillar extending through the ferrite body from a first surface of the ferrite body to a second surface of the ferrite body opposite the first surface, and a second conductive pillar extending through the ferrite body from the first surface to the second surface; and
a planar substrate coupled to the first surface of the ferrite body, the planar substrate electrically connecting a first end of the first conductive pillar to a first end of the second conductive pillar,
wherein a second end of the first conductive pillar provides a first inductor terminal that is electrically connected to the circuit board, and a second end of the second conductive pillar provides a second inductor terminal that is electrically connected to the circuit board.

11. The power conversion module of claim 10, wherein the planar substrate comprises direct bonded copper (DBC).

12. The power conversion module of claim 11, wherein the DBC comprises a ceramic substrate and a copper conductor bonded to the ceramic substrate, the copper conductor electrically connecting the first end of the first conductive pillar to the first end of the second conductive pillar.

13. The power conversion module of claim 12, wherein the ceramic substrate comprises at least one of aluminum nitride, silicon nitride, or aluminum oxide.

14. The power conversion module of claim 12, wherein the first conductive pillar and the second conductive pillar are formed of copper.

15. The power conversion module of claim 11, further comprising a heat sink coupled to the DBC opposite the ferrite core.

16. The power conversion module of claim 10, wherein the planar substrate comprises a printed circuit board (PCB) having a conductive trace electrically connecting the first end of the first conductive pillar to the first end of the second conductive pillar.

17. The power conversion module of claim 10, wherein the ferrite core further includes a third conductive pillar extending through the ferrite body from the first surface to the second surface and a fourth conductive pillar extending through the ferrite body from the first surface to the second surface, the planar substrate electrically connecting a first end of the third conductive pillar to a first end of the fourth conductive pillar.

18. The power conversion module of claim 17, wherein a second end of the third conductive pillar provides a third inductor terminal, and a second end of the second conductive pillar provides a fourth inductor terminal, the first inductor terminal and the second inductor terminal providing a first inductor phase, and the third inductor terminal and the fourth inductor terminal providing a second inductor phase.

19. The power conversion module of claim 10, further comprising a switcher die attached to the circuit board adjacent to the inductor.

20. A method of forming an inductor, the method comprising:
attaching a ferrite core to a planar substrate, the ferrite core including a ferrite body, a first conductive pillar extending through the ferrite body from a first surface of the ferrite body to a second surface of the ferrite body opposite the first surface, and a second conductive pillar extending through the ferrite body from the first surface to the second surface;
electrically connecting a first end of the first conductive pillar to a first end of the second conductive pillar using the planar substrate; and
providing a first inductor terminal using a second end of the first conductive pillar and providing a second inductor terminal using a second end of the second conductive pillar.
